(19) United States
(12) Patent Application Publication
(10) Pub. No.: US 2018/0062008 A1
(43) Pub. Date: Mar. 1, 2018

(54) METHOD AND SYSTEM FOR MANUFACTURING ELECTRICAL CONTACT FOR PHOTOVOLTAIC STRUCTURES

(71) Applicant: SolarCity Corporation, San Mateo, CA (US)

(72) Inventors: Zhigang Xie, San Jose, CA (US); Yangsen Kang, Santa Clara, CA (US); Phillip M. Wu, San Mateo, CA (US); Jianhua Hu, Palo Alto, CA (US)

(73) Assignee: SolarCity Corporation, San Mateo, CA (US)

(21) Appl. No.: 15/244,885

(22) Filed: Aug. 23, 2016

(51) Int. Cl. H01L 31/0224; H01L 31/0376; H01L 31/18; C23C 14/22; C23C 14/08; C23C 14/16; C23C 14/58

(52) U.S. Cl. CPC H01L 31/022466; H01L 31/03762; H01L 31/1804; H01L 31/1884; C23C 14/5806; C23C 14/228; C23C 14/086; C23C 14/16; H01L 31/1864

(57) ABSTRACT

A system for fabrication of a photovoltaic structure is provided. During fabrication, the system can deposit a doped amorphous Si layer on a first surface of a crystalline Si substrate; and deposit, using a physical vapor deposition machine, a transparent conductive oxide layer on the doped amorphous Si layer. The deposited transparent conductive oxide layer can include In₂O₃ doped with TiO₂ and Ta₂O₅, and depositing the transparent conductive oxide layer can involve maintaining the Si substrate at a temperature below 130° C. The system can further deposit a metallic layer on the transparent conductive oxide layer, and anneal the transparent conductive oxide layer.

### FIELD OF THE INVENTION

This generally relates to the fabrication of photovoltaic structures. More specifically, this is related to the fabrication of the electrical contact for photovoltaic structures.

### Definitions

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BACKGROUND

Advances in photovoltaic technology, which is used to make solar panels, have helped solar energy gain mass appeal among those wishing to reduce their carbon footprint and decrease their monthly energy costs. Most of the current solar cell manufacturing facilities, however, are insufficiently equipped and/or not optimized for large-scale production. The emerging solar market demands factories that can produce hundreds of megawatts, if not gigawatts, of solar cells per year. The design, size, and throughput of present facilities are not intended for such high-volume manufacturing. Hence, various new designs in the manufacturing process are needed.

In addition to high throughput and low cost, it is also important to design a fabrication system/process that does not induce damages to the cell structures. Although certain damages do not affect solar cell performance in the short term, they may degrade the long-term reliability of the solar cell.

### SUMMARY

One embodiment can provide a system for fabrication of a photovoltaic structure. During fabrication, the system can deposit a doped amorphous Si layer on a first surface of a crystalline Si substrate; and deposit, using a physical vapor deposition machine, a transparent conductive oxide layer on the doped amorphous Si layer. The deposited transparent conductive oxide layer can include In₂O₃ doped with TiO₂ and Ta₂O₅, and depositing the transparent conductive oxide layer can involve maintaining the Si substrate at a temperature below 130° C. The system can further deposit a metallic layer on the transparent conductive oxide layer, and anneal the transparent conductive oxide layer.

In a variation of this embodiment, depositing the transparent conductive oxide layer can involve maintaining the Si substrate at a temperature below 80° C.

In a variation of this embodiment, depositing the transparent conductive oxide layer can involve injecting H₂ or water vapor into the physical vapor deposition machine.

In a variation of this embodiment, a by-weight concentration of the TiO₂ can be between 0.2% and 2%, and a by-weight concentration of the Ta₂O₅ can be between 0 and 1%.

In a variation of this embodiment, annealing the transparent conductive oxide layer can involve subjecting the photovoltaic structure to a temperature ranging from 150° C. to 230° C.

In a further variation, annealing the transparent conductive oxide layer can involve subjecting the photovoltaic structure to the temperature for a time period between three and 90 minutes.

In a variation on this embodiment, annealing the transparent conductive oxide layer can be performed after the metallic layer is deposited, and the metallic layer can be deposited in the same physical vapor deposition tool without disrupting a vacuum, and the annealing can be performed in an oxygen-free environment to prevent oxidation of the metallic layer.

In a variation on this embodiment, annealing the transparent conductive oxide layer can be performed before the deposition of the metallic layer, and the annealing can be performed inside the physical vapor deposition tool without disrupting a vacuum.

In a further variation, depositing the metallic layer involves heating the Si substrate, thereby facilitating at least a portion of the annealing of the transparent conductive oxide layer.

### BRIEF DESCRIPTION OF THE FIGURES

FIG. 1 shows an exemplary photovoltaic structure, according to one embodiment.

FIG. 2 shows an exemplary process of fabricating a photovoltaic structure, in accordance with one embodiment.

FIG. 3 shows an exemplary large-scale fabrication system, according to one embodiment.

FIG. 4 shows an exemplary large-scale fabrication process of photovoltaic structures, according to one embodiment.

FIG. 5 shows an exemplary large-scale fabrication process of photovoltaic structures, according to one embodiment.

FIG. 6 shows an exemplary physical vapor deposition system, according to one embodiment.

FIG. 7 shows an exemplary fabrication system, according to one embodiment.

FIG. 8 shows an exemplary fabrication process, according to one embodiment.

FIGS. 9A-9C show the highly-accelerated temperature and humidity stress test (HAST) results, according to one embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention can solve the technical problem of improving the production throughput for photovoltaic structures with electroplated metallic grids. More specifically, the proposed solution can ensure the long-term reliability of photovoltaic structures by achieving a high-quality transparent conductive oxide (TCO) film, which can also serve as a moisture barrier, while maintaining low interface defect density (Dᵢₜ). During fabrication, a novel TCO layer doped with Ti and Ta can be deposited using a physical vapor deposition (PVD) technique, without intentional heating of the substrate. More specifically, the TCO layer can be deposited at a temperature lower than 150° C. The as-deposited TCO film is often in amorphous form, and thermal annealing can be used to improve the electro-optical properties of the TCO film. For photovoltaic structures with electroplated Cu grids, a metallic seed layer (e.g., a Cu seed layer) can also be deposited on the TCO layer using a PVD process. To improve throughput, the TCO layer and the Cu seed layer can be deposited using the same PVD tool without disrupting the vacuum, and can also be annealed simultaneously.

Photovoltaic Structures with Electroplated Metallic Grids

Electroplated metallic electrode grids (e.g., electroplated Cu grids) have been shown to exhibit lower resistance than conventional aluminum or screen-printed-silver-paste electrodes. Such low electrical resistance can be essential in achieving high-efficiency photovoltaic structures. In addition, electroplated copper electrodes can also tolerate microcracks better, which may occur during a subsequent cleaving process. Such microcracks might impair silver-paste-electrode cells. Plated-copper electrode, in contrast, can preserve the conductivity across the cell surface even if there are microcracks. The copper electrode's higher tolerance for microcracks allows the use of thinner silicon wafers, which can reduce the overall fabrication cost. More details on using copper plating to form low-resistance electrodes on a photovoltaic structure are provided in U.S. patent application Ser. No. 13/220,532, Attorney Docket No. P59-1NUS, entitled “SOLAR CELL WITH ELECTROPLATED GRID,” filed on Aug. 29, 2011, the disclosure of which is incorporated herein by reference in its entirety.

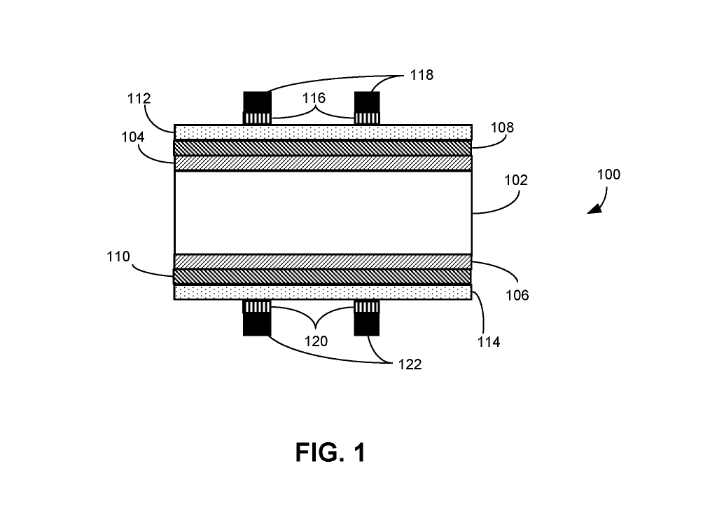

FIG. 1 shows an exemplary photovoltaic structure, according to one embodiment. In FIG. 1, photovoltaic structure 100 can include base layer 102, front and back passivation layers 104 and 106, emitter layer 108, surface-field layer 110, front and back TCO layers 112 and 114, a front electrode grid that can include Cu seed layer 116 and electroplated bulk Cu layer 118, and a back electrode grid that can include Cu seed layer 120 and electroplated bulk Cu layer 122.

Base layer 102 can include various materials, such as undoped or lightly doped monocrystalline silicon and/or undoped or lightly doped microcrystalline silicon. Passivation layers 104 and 106 can include various dielectric materials, such as silicon oxide (SiOₓ) hydrogenated SiOₓ, silicon nitride (SiNₓ), hydrogenated SiNₓ, aluminum oxide (AlOₓ), silicon oxynitride (SiON), hydrogenated SiON, and any combination thereof. In addition to dielectric material, the passivation layers may also include intrinsic (e.g., undoped) silicon in various forms, such as single crystalline Si, polycrystalline Si, amorphous Si, and any combination thereof. The passivation layers can be formed using a wet process, such as wet or steam oxidation. Emitter layer 108 can include heavily doped wide bandgap material, such as amorphous Si (a-Si) or hydrogenated a-Si (a-Si:H). If base layer 102 is lightly doped, emitter layer 108 can have a conductive doping type opposite to that of base layer 102. Surface-field layer 110 can also include heavily doped wide bandgap material, such as a-Si or a-Si:H. The conductive doping type of surface-field layer 110 can be opposite to that of emitter layer 108. In some embodiments, emitter layer 108 and/or surface-field layer 110 can have a graded doping profile, with a lower doping concentration near the base/emitter or base/surface-field layer interface. The formation of emitter layer 108 and/or surface-field layer 110 can involve a chemical-vapor-deposition (CVD) epitaxial process, such as a plasma-enhanced chemical-vapor-deposition (PECVD) process. In the example shown in FIG. 1, emitter layer 108 is positioned on the front side of the photovoltaic structure, facing the incident light. In practice, the emitter can also be placed on the back side of the photovoltaic structure, facing away the incident light.

Front and back TCO layers 112 and 114 can play an important role in ensuring high efficiency and long-term reliability of the photovoltaic structures. In addition to serving as an anti-reflection coating (ARC) layer and being part of the current-collecting electrode, a well-designed TCO layer can also serve as a moisture barrier. Conventional approaches to forming TCO layers 112 and 114 can include depositing, by a PVD process (e.g., sputtering, ion-plating, evaporation, etc.) various TCO materials that can include indium-tin-oxide (ITO), aluminum-doped zinc-oxide (ZnO:Al), gallium-doped zinc-oxide (ZnO:Ga), tungsten-doped indium oxide (IWO), Zn—In—Sn—O (ZITO), and their combinations. To obtain a high-quality TCO film, the TCO deposition often involves increasing the substrate temperature, e.g., to 200° C. or above. However, sputtering at a high temperature means that the high energy ions may bombard the wafer surface, possibly damaging the fragile passivation layers and increasing the Dᵢₜ at the TCO/a-Si interface.

To prevent degradation to the passivation layers and to reduce the Dᵢₜ at the surface of the emitter or surface-field layer, in some embodiments, the TCO layers are formed at a relatively low temperature (e.g., below 150° C., preferably below 130° C.). For example, the TCO layers can be formed using a PVD technique (e.g., sputtering) without intentional heating. Because a typical PVD process (e.g., DC or RF sputtering) may inherently result in heating of the substrate, a cooling system (e.g., a water cooling system or a liquid nitrogen cooling system) may be needed to keep the substrate at a relatively low temperature. In one embodiment, an RF sputtering system equipped with water cooling can be used, and the substrate temperature can be maintained at 80° C. or below during sputtering.

The low temperature sputtering of the TCO often results in amorphous TCO films. The electro-optical properties of amorphous TCO typically cannot meet the requirements of high-efficiency photovoltaic structures. Thermal treatment (e.g., annealing) can transform the TCO from an amorphous state to a multicrystalline state, improving the properties of the TCO films. The resulting TCO films can have high transparency over a wide wavelength range and low electrical resistivity. For multi-crystalline TCO, larger grain size can lead to better optical properties. In order for the TCO to respond better to the thermal treatment (i.e., to form larger grains), the TCO material should have a lower metallic doping concentration. On the other hand, higher metallic doping may be needed to reduce the electrical resistivity. In order to meet both the optical and electrical requirements, it is important to design the TCO material composition.

In some embodiments, the TCO material can include indium oxide (In₂O₃) doped with Ti and Ta. More specifically, the TCO material can include TiO₂ doped In₂O₃, with the doping concentration (by weight) of TiO₂ in the range between 0.2% and 2%, preferably between 0.5% and 1%. Alternatively, the TCO material can include In₂O₃ doped with both TiO₂ and Ta₂O₅, with the doping concentration (by weight) of TiO₂ in the range between 0.2% and 2%, preferably between 0.5% and 1%, and the doping concentration (by weight) of Ta₂O₅ in the range between 0 and 1%, preferably between 0.2% and 0.6%. Other types of TCO materials are also possible, including but not limited to: ITO with low (e.g., less than 2% by weight) SnO₂ doping, tungsten doped In₂O₃ (IWO), and cerium doped indium oxide (ICeO).

The TCO layer that is based on Ti/Ta-doped indium oxide not only can provide superior electro-optical properties after annealing, but also can serve as a high-quality moisture barrier. In addition, this type of TCO film can prevent the diffusion of the Cu ions from the thin metallic seed layer (e.g., Cu seed layer 116 or 120). The Cu seed layer can be formed using a PVD technique (e.g., sputtering or evaporation) in order to improve the adhesion between the electroplated Cu grid and the underlying TCO layer, because high-energy atoms sputtered from the target can adhere well to the TCO layer.

As discussed previously, electroplated Cu grids can provide a number of advantages, such as reduced resistance and increased tolerance to microcracks. However, the fabrication of a reliable Cu grid can involve depositing a Cu seed layer using a PVD process, which can complicate the fabrication process of photovoltaic structures with Cu grids. More specifically, after the deposition of the TCO layers, one may need to take the photovoltaic structures out of the PVD tool for annealing, and then send them back to the same PVD tool or to a different PVD tool for deposition of the Cu seed layer. This can increase the equipment wait time, because the PVD chamber needs to be pumped down before each deposition.

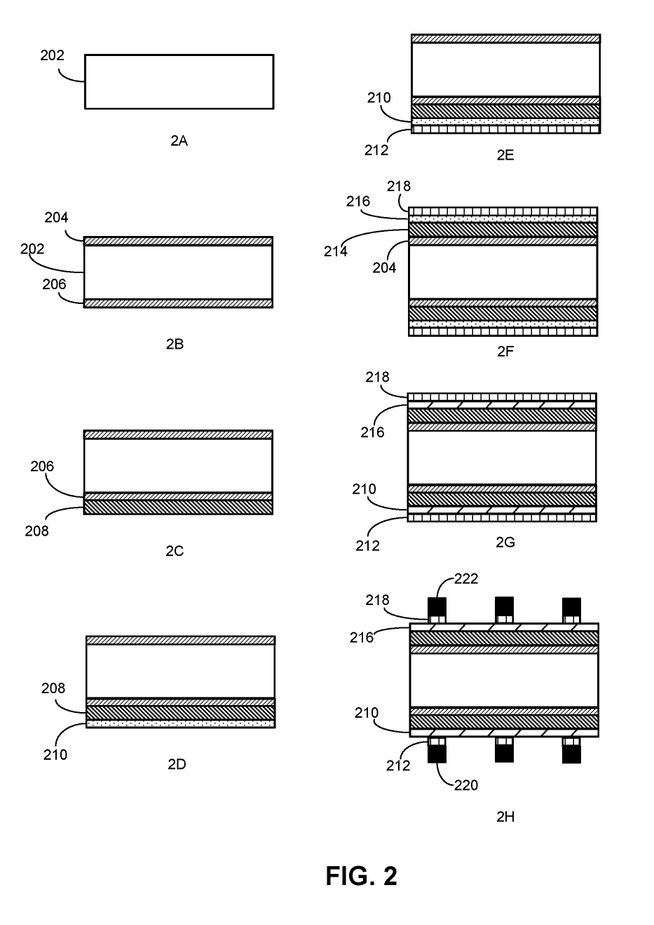

FIG. 2 shows an exemplary process of fabricating a photovoltaic structure, in accordance with one embodiment. In operation 2A, substrate 202 can be prepared. Substrate 202 can include a crystalline-Si (c-Si) wafer (e.g., a monocrystalline or polycrystalline silicon wafer). In some embodiments, preparing c-Si substrate 202 can include standard saw-damage etching (which removes the damaged outer layer of Si substrate 202) and surface texturing. The c-Si substrate 202 can be lightly doped with either n-type or p-type dopants. In one embodiment, c-Si substrate 202 can be lightly doped with n-type dopants (e.g., phosphorus). In addition to c-Si, other materials (such as metallurgical-Si) can also be used to form substrate 202.

In operation 2B, front and back passivation layers 204 and 206 can be formed on the front and back surfaces, respectively, of substrate 202. The passivation layers can also function as quantum-tunneling barrier (QTB) layers. In some embodiments, forming passivation layers 204 and 206 can involve a wet oxidation process, which can form a thin layer of SiOₓ with x less than two on both sides of substrate 202. The thickness of passivation layers 204 and 206 can be between 1 and 50 angstroms.

In operation 2C, heavily doped emitter layer 208 can be formed on the back side of substrate 202. Forming emitter layer 208 can involve a CVD process. In some embodiments, emitter layer 208 can include hydrogenated a-Si with a graded-doping profile. More specifically, the doping concentrate of emitter layer 208 can increase from the region adjacent to the emitter/base interface. For n-type doped substrate 202, emitter layer 208 can be doped with p-type dopants (e.g., boron). The thickness of emitter layer 208 can be between 2 and 50 nm.

In operation 2D, TCO layer 210 can be formed on emitter layer 208. Forming TCO layer 210 can involve a PVD process, such as sputtering. In some embodiments, to prevent damages to the surface of emitter layer 208, forming TCO layer 210 can involve low-temperature sputtering, which can be performed without intentional heating of the substrate or with active cooling of the substrate. Without intentional heating of the substrate, the temperature of the substrate can remain below 130° C. during sputtering. Water cooling can be introduced during sputtering to further reduce the substrate temperature. In some embodiments, the temperature of the substrate can be kept below 80° C. While forming TCO layer 210, the PVD chamber can be filled with production gas, such as Ar and O₂, for generating plasmas. In some embodiments, additional reactive gas, such as H₂ and water vapor, can also be injected into the PVD chamber. More specifically, H₂ can be injected into the PVD chamber in the form of ArH₂, with Ar being the delivering gas. Injecting water vapor and H₂ into the deposition chamber can improve the TCO film quality under low temperature conditions.

The low-temperature sputtering can ensure low Dᵢₜ at the emitter/TCO interface, and prevent damages to the underlying passivation layer. However, TCO layer 210 formed under the low-temperature condition typically is in amorphous state, having inferior electro-optical properties. Thermal annealing will be needed to improve the electro-optical properties of TCO layer 210.

In some embodiments, TCO layer 210 can include indium oxide (In₂O₃) doped with Ti and Ta, which can provide superior electro-optical properties after annealing. The doping of the Ti and Ta can be carefully controlled to optimize the electro-optical properties of TCO layer 210. More specifically, TCO layer 210 can include TiO₂ doped In₂O₃, with the doping concentration (by weight) of TiO₂ in the range between 0.2% and 2%, preferably between 0.5% and 1%. Alternatively, TCO layer 210 can include In₂O₃ doped with both TiO₂ and Ta₂O₅, with the doping concentration (by weight) of TiO₂ in the range between 0.2% and 2%, preferably between 0.5% and 1%, and the doping concentration (by weight) of Ta₂O₅ in the range between 0 and 1%, preferably between 0.2% and 0.6%. Other types of TCO materials can also be possible, including but not limited to: ITO with low (e.g., less than 2% by weight) SnO₂ doping, tungsten doped In₂O₃ (IWO), and cerium doped indium oxide (ICeO).

In operation 2E, metallic seed layer 212 can be formed on TCO layer 210. Forming metallic seed layer 212 can also involve a PVD process. In some embodiments, metallic seed layer 212 can be formed using the same PVD tool that forms TCO layer 210 without disrupting the vacuum, meaning that the photovoltaic structures remain in the same vacuum environment during the deposition of the both layers. This can significantly reduce the processing time, because there is no need to pump down the PVD chamber or chambers between processes.

In operation 2F, the n-side layer stack, including front surface-field layer 214, front TCO layer 216, and front metallic seed layer 218, can be formed using processes that are similar to the ones used in operations 2C-2E. Front surface-field layer 214 can have a doping type that is opposite to that of emitter layer 208. Front TCO layer 216 can be similar to back TCO layer 210, and front metallic seed layer 218 can be similar to back metallic seed layer 212.

In operation 2G, the photovoltaic structure can be sent to an annealing station for thermal annealing. More specifically, TCO layers 210 and 216 and metallic seed layers 212 and 218 can be annealed simultaneously. After the thermal annealing, TCO layers 210 and 216 can transition from the amorphous state to a multicrystalline state, improving their electro-optical properties. The annealing temperature can be maintained between 150 and 230° C., preferably between 200 and 230° C. If the temperature is too low, the amorphous-to-multicrystalline conversion of the TCO layers may not be ideal; if the temperature is too high, the p-n junction may be damaged. The annealing dwell time, which refers to the amount of time that the photovoltaic structures spend at the annealing station, can be kept between three minutes and 90 minutes, preferable between 20 and 40 minutes. In some embodiments, the annealing station can include an inline oven. To prevent oxidation of Cu seed layers 212 and 218, the O₂ concentration in the annealing oven needs to be carefully controlled to be below 400 ppm. In some embodiments, a strong flow of purging gas (e.g., N₂) can be maintained in the annealing oven. Alternatively, thermal annealing can be performed in a vacuum.

In operation 2H, the bulk portion of front and back metallic grids (e.g., layers 220 and 222) can be formed on metallic seed layers 212 and 218, respectively. In some embodiments, forming bulk metallic layers 220 and 222 can involve an electroplating process. In further embodiments, dry film resist can be used to pattern the surface of Cu seed layers 212 and 218, and Cu ions can be deposited into the windows defined by the dry film resist during the electroplating process. Subsequent to electroplating, the dry film resist can be stripped off, and metallic seed lasers 212 and 218 can be partially etched, using bulk layers 220 and 222 as masks, to expose underlying TCO layers 210 and 216, respectively.

The process shown in FIG. 2 uses the fabrication of a single wafer as an example. In practice, large- or very-large-scale fabrication of photovoltaic structures are needed, and conventional fabrication tools and processes may need to be modified to meet the throughput requirements of the large- or very-large-scale fabrication of photovoltaic structures.

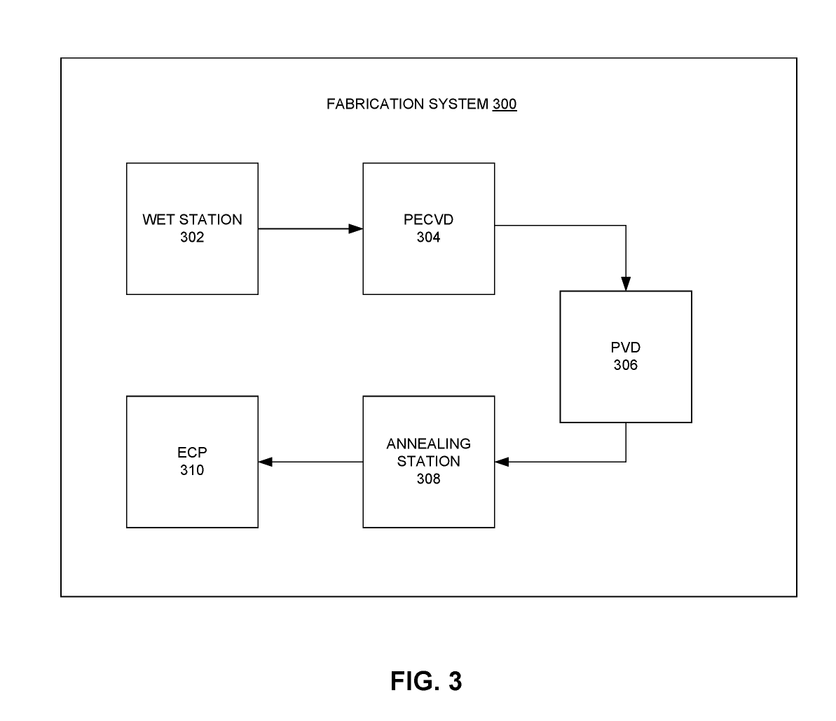

FIG. 3 shows an exemplary large-scale fabrication system, according to one embodiment. In FIG. 3, fabrication system 300 can include wet station 302, PECVD tool 304, PVD tool 306, annealing station 308, and ECP station 310.

Wet station 302 can be used to perform a series of wet processes (e.g., saw-damage removing, random texturing, and wet oxidation) on crystalline Si substrates. In some embodiments, Si substrates can also be cleaned by being slowly pulled out of hot deionized water. Wet station 302 can process Si substrates in batches, with each batch including tens or hundreds of Si substrates. Alternatively, wet station 302 can process the substrates in an inline fashion. In some embodiments, wet station 302 can be configured to form the front and back passivation layers simultaneously using a wet oxidation technique.

PECVD tool 304 can be used to form doped amorphous Si (a-Si) layers, which can act as emitter and surface-field layers, on the front and back surfaces of the Si substrates. In addition, PECVD tool 304 can be used to form intrinsic a-Si layers, which can act as passivation layers. PECVD tool 304 can process Si substrates in batches or in an in-line fashion. In some embodiments, a wafer carrier that can carry over 100 Si wafers (e.g., 5-inch or 6-inch square or pseudo-square Si wafers) can be used inside the PECVD tool to allow simultaneous material deposition on those wafers. The wafer carrier can be a graphite or carbon fiber composite (CFC) carrier coated with a low-porosity material, such as pyrolytic carbon or silicon carbide. The wafer carrier may also include a non-flat surface or a partially carved-out structure at the bottom of the wafer-holding pockets. Photovoltaic structures emerging from PECVD tool 304 can include an emitter layer on one side and a surface-field layer on the other side.

PVD tool 306 can be configured to sequentially deposit a thin layer of TCO material and one or more metallic layers on one or both sides of the photovoltaic structures. In some embodiments, PVD tool 306 can include a sputtering machine, such as a radio-frequency (RF) magnetron sputtering machine. In further embodiments, the RF magnetron sputtering machine can include one or more rotary targets coupled to a periodically tuned capacitor. This arrangement can ensure a uniform etching profile of the targets, which can reduce cost and time for maintenance. A detailed description of the rotary targets can be found in U.S. patent application Ser. No. 14/142,605, entitled “Radio-Frequency Sputtering System with Rotary Target for Fabricating Solar Cells,” filed Dec. 27, 2013, the disclosure of which is incorporated herein by reference in its entirety.

In some embodiments, PVD tool 306 can include a multiple-target inline or batch sputtering tool (e.g., an RF magnetron sputtering tool). An inline sputtering tool can deposit materials on a number of substrates moving through the sputtering chamber. A batch sputtering tool can deposit material on a number of substrates that remain stationary in the sputtering chamber. In a large-scale fabrication setting, an inline sputtering tool is a preferred choice for deposition of the TCO layers. The multiple targets inside the deposition chamber of PVD tool 306 can include a set of Ti-doped or Ti/Ta doped In₂O₃ targets for deposition of the TCO layers and a set of Cu targets for deposition of the metallic seed layers. In some embodiments, the targets can be located on both sides of the photovoltaic structures to enable single-pass deposition on both sides. In some embodiments, the multiple targets can be electrically insulated from each other, and can be sequentially biased to allow one active target at a time. Alternatively, PVD tool 306 can include a rotational shutter to expose only one target to the deposition surface at a time.

In some embodiments, PVD tool 306 can include multiple chambers, each configured to deposit a particular type of material (e.g., TCO or Cu). The multiple chambers can be included in the same vacuum environment, and photovoltaic structures can be transferred from one chamber to the other without disrupting the vacuum. Both the multiple-target PVD or the multi-chamber PVD can allow sequential deposition of the multiple layers (e.g., a TCO layer and one or more metallic layers on each side) without disrupting the vacuum, resulting in a high throughput PVD process.

Annealing station 308 can include various annealing tools that can perform batch annealing, including but not limited to: a convection oven or an inline belt-driven furnace. A large number of photovoltaic structures can be placed inside a wafer cassette and sent into annealing station 308 for batch or inline annealing. To prevent oxidation of the Cu seed layer, the oven or inline furnace needs to be oxygen free. In some embodiments, annealing station 308 can be purged with high purity N₂ at a high flow rate. More specifically, the oxygen level in annealing station 308 can be kept below 400 ppm. Alternatively, the annealing can be performed in a vacuum, and radiators can be used as heat sources.

ECP station 310 can include a large electrolyte bath and a moving cathode. Photovoltaic structures attached to the moving cathode can be plated with metallic ions as they move through the electrolyte bath. More specifically, specially designed wafer-holding jigs can carry the photovoltaic structures in such a way that both the front and back sides of the photovoltaic structures are exposed to the electrolyte solution. Therefore, metallic ions (e.g., Cu ions) can be deposited on both sides of the photovoltaic structures as the wafer-holding jigs move through the electrolyte bath. In other words, the front and back metallic grids can be formed simultaneously. Photovoltaic structures emerging from ECP station 310 can go through further fabrication processes, such as striping of the photoresist, etching off of the Cu seed layer, and tin immersion, before being sent to the testing and packing stations.

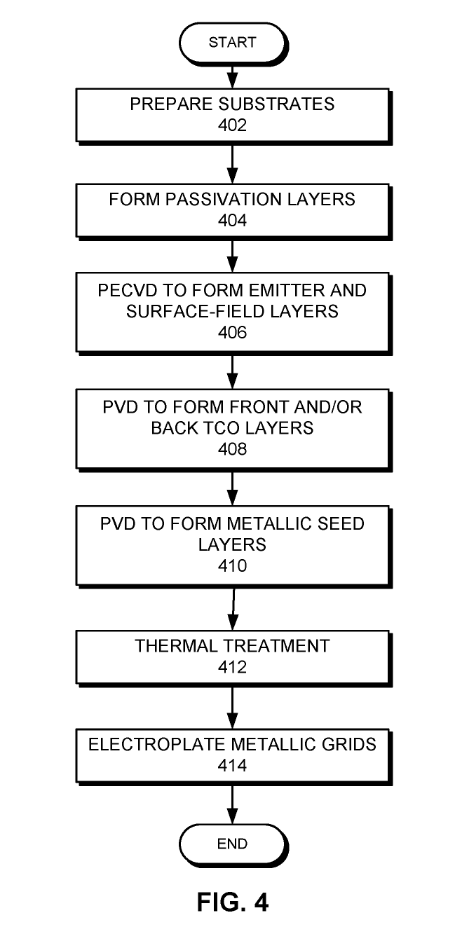

FIG. 4 shows an exemplary large-scale fabrication process of photovoltaic structures, according to one embodiment. The following process is described in conjunction with FIG. 3.

During fabrication, a plurality of substrates can be prepared (operation 402). The substrates can go through, at wet station 302, saw damage removing, random texturing, and cleaning. Subsequently, front and back passivation layers can be formed on the front and back surfaces, respectively, of the substrates (operation 404). In some embodiments, forming the passivation layers can include wet oxidation performed at wet station 302, and the passivation layers can also function as quantum-tunneling barrier (QTB) layers.

After the wet processes, the substrates can be dried and sent to PECVD tool 304 for deposition of the emitter layer and surface-field layer (operation 406). In some embodiments, over 100 of substrates can be loaded on to a wafer carrier and sent inside the PECVD chamber for the deposition of a p-type doped a-Si layer (the emitter layer) and an n-type doped a-Si layer (the surface field layer). In some embodiments, after deposition of the emitter layer on one side, the substrates may be turned over for deposition of a surface-field layer on the other side. Alternatively, the deposition sequence may change so that the surface-field layer can be deposited first.

After the PECVD operation(s), the multilayer structures can be sent to PVD tool 306 for the deposition of front and/or back TCO layers (operation 408). The back TCO layer can facilitate the bifacial operation of the photovoltaic structures. Alternatively, only the front (e.g., the side that faces incident light) TCO layer might be needed. In some embodiments, deposition of the front and/or back TCO layers can be performed without intentional heating of the substrates. In further embodiments, deposition of the front and/or back TCO layers can involve active cooling of the substrates. For example, PVD tool 306 can include a water cooling system that can keep the substrates at or below 80° C. Other cooling methods can also be possible, such as liquid N₂ cooling. The TCO films formed using low-temperature PVD can be in an amorphous state.

In some embodiments, deposition of the front and/or back TCO layers can be performed simultaneously in one single pass. For example, the substrates can be placed in a special carrier with both surfaces exposed, and TCO targets can be placed on both sides of the substrates. The sputtering targets can include, but are not limited to: TiO₂ doped In₂O₃, TiO₂-and-Ta₂O₅ doped In₂O₅, and ITO with low SnO₂ doping, IWO, and ICeO. The low density targets (i.e., TWO and ICeO) can typically be used in a reactive plasma deposition (RPD) process. To prevent arcing and achieve stable sputtering, the targets need to have a high purity level (e.g., greater than 99%).

During the TCO deposition, the deposition chamber of PVD tool 306 can be filled with Ar and O₂, which can generate plasmas. In some embodiments, H₂ and water vapor can also be injected into the PVD chamber to improve the quality of the TCO films.

Subsequent to the formation of the front and/or back TCO layers, the multilayer structures can remain in the same PVD tool for deposition of metallic seed layers (e.g., Cu seed layers) on the front and back sides of the multilayer structures (operation 410). More specially, the TCO layers and the metallic layers can be deposited in the same PVD tool without disrupting the vacuum. This can significantly reduce the processing time, because there is no need to pump down the chambers between processes.

In addition to a Cu seed layer, PVD tool 306 may also deposit one or more metallic adhesive layers between the TCO layer and Cu seed layer. These adhesive layers can improve the adhesion between any subsequently deposited metallic layer and the TCO layer. The metallic seed layers typically can include the same metallic material as the subsequently plated metallic grids, whereas the metallic adhesive layers can include Cu, Ni, Ag, Ti, Ta, W, TiN, TaN, WN, TiW, NiCr, and their combinations.

Subsequent to the deposition of the multiple layers (e.g., TCO layers and Cu seed layers), the multilayer structures can be taken out of the PVD tool 306 and sent to annealing station 308 for thermal treatment (operation 412). At annealing station 308, both the TCO and Cu seed layers can be annealed simultaneously. The annealing temperature can be between 150 and 230° C., and the annealing dwell time can be between 20 and 40 minutes. In some embodiments, a strong flow of purging gas can be introduced at annealing station 308 to prevent oxidation of the previously deposited metallic layers.

After annealing, the photovoltaic structures can be sent to an electroplating station for plating of the front and back side metallic grids (operation 412). The photolithography process that defines the grid pattern can be a standard process and is not shown in the flowchart.

In the example shown in FIGS. 2 and 4, the passivation layers include SiOₓ formed using a wet oxidation technique. In practice, other types of passivation materials can also be possible, which can involve different fabrication processes. For example, it may be challenging to simultaneously obtain front and back passivation layers that include intrinsic a-Si.

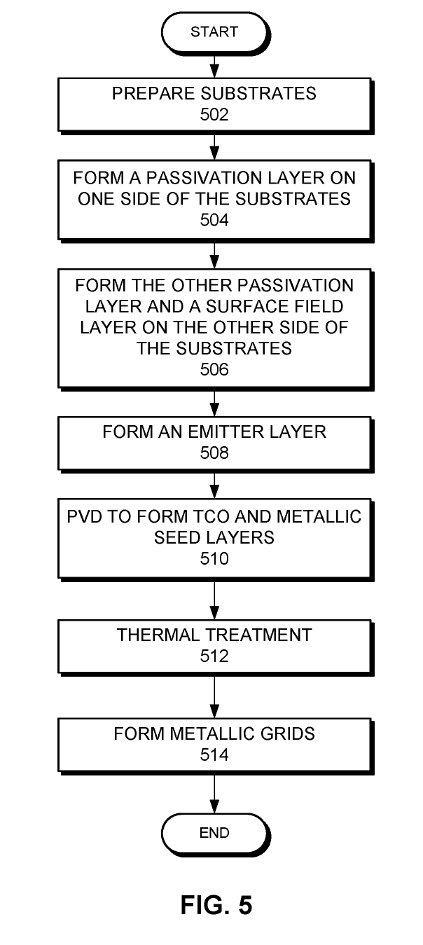

FIG. 5 shows an exemplary large-scale fabrication process of photovoltaic structures, according to one embodiment. During fabrication, a plurality of c-Si substrates can be prepared (operation 502). Operation 502 can be similar to operation 402. The c-Si substrates can be sent to a CVD tool for deposition of a passivation layer on one side (operation 504). In some embodiments, the passivation layer can include intrinsic a-Si, and the thickness of the intrinsic a-Si layer can be between 1 and 50 angstroms. For c-Si substrates that are lightly doped with n-type dopants, this passivation layer can be referred to as the p-side passivation layer, meaning that it is positioned between the substrate and the p-type doped emitter layer.

Subsequently, the substrates can be turned over, and another passivation layer followed by a surface field layer can be formed on the other side of the substrates (operation 506). This second passivation layer can be similar to the previously formed passivation layer. For n-type doped substrates, the surface-field layer can include n-type doped a-Si. In some embodiments, the second passivation layer and the surface-field layer can be formed within the same CVD chamber, without disrupting the vacuum.

Subsequent to the formation of the surface-field layer, the substrates can be turned over once again and an emitter layer can be formed on the previously formed p-type passivation layer (operation 508). The emitter layer can include p-type doped a-Si. In some embodiments, operations 504-508 can be performed by different CVD tools. Alternatively, operations 504-508 can be performed by the same CVD tool.

After the CVD operations, the substrates can be sent to a PVD tool for deposition of front and back TCO layers and front and back metallic seed layers (operation 510). Operation 510 can be similar to operations 408 and 410. In some embodiments, the front and back TCO layers can be formed using a single pass. This can be achieved by placing the TCO targets on both sides of the substrates. In some embodiments, the TCO layers can be formed under a low temperature condition, with the substrate temperature maintained at a temperature below 130° C., or below 80° C. The TCO targets can include In₂O₃ doped with small amounts of TiO₂ and Ta₂O₅. The front and back metallic seed layers can also be formed using a single pass. Moreover, the TCO layers and the metallic seed layers can be formed using the same PVD tool, without disrupting the vacuum. This can significantly improve the fabrication throughput, compared to the approaches that require the substrates to be taken out of the PVD chamber after the TCO deposition.

The photovoltaic structures that include both the n-side and p-side layer stacks can then be sent to an annealing station for thermal treatment (operation 512). Operation 512 can be similar to operation 412. In some embodiments, the photovoltaic structures can be sent to an annealing oven with the oven temperature set at about 200° and remain in the annealing oven for at least 20 minutes.

After thermal annealing, metallic grids can be formed on both surfaces of the photovoltaic structures (operation 514). In some embodiments, forming the metallic grids can include patterning the surfaces using dry film resist, electroplating, removing the dry film resist, etching the metallic seed layers, and depositing a protective layer over the top and sidewalls of the metallic grids. Another annealing operation can also be optional to anneal the electroplated metallic grids.

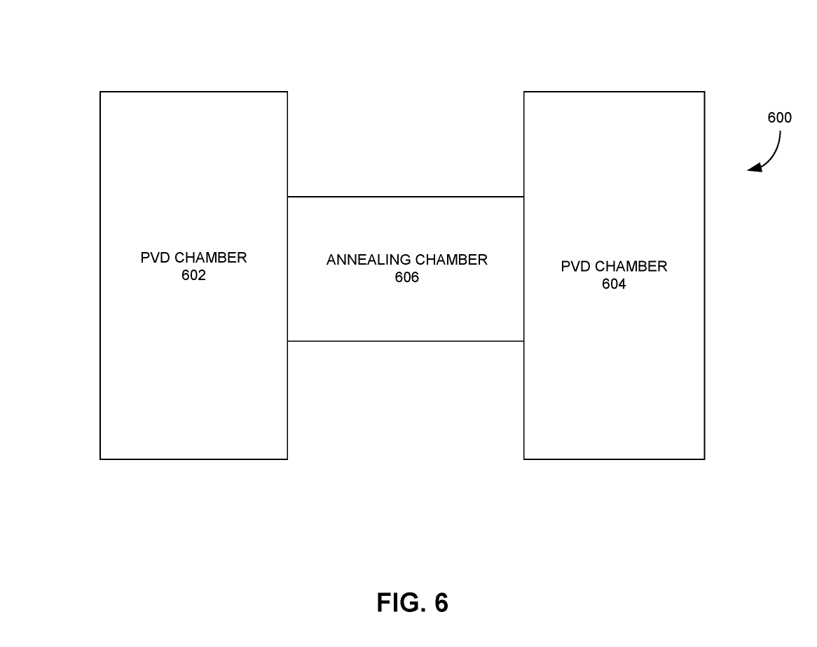

Because thermal effects on the TCO can be cumulative, in some embodiments, the TCO annealing can also occur in a distributed manner, possibly without involving a separate annealing tool. FIG. 6 shows an exemplary physical vapor deposition system, according to one embodiment. PVD system 600 includes multiple PVD chambers, such as PVD chambers 602 and 604, and annealing chamber 606.

During fabrication, each of the PVD chambers can be used to deposit a film layer of a particular type. In some embodiments, PVD system 600 can include a sputtering tool, and each sputtering chamber can be equipped with sputtering targets of a particular type. For example, PVD chamber 602 can be used to deposit a TCO layer on one or both sides of the photovoltaic structures, and can include a set of targets made of TCO materials. In some embodiments, PVD chamber 602 can include TiO₂ or TiO₂/Ta₂O₅ doped In₂O₃ targets. More specifically, TCO layers formed in PVD chamber 602 can include TiO₂ or Ta₂O₅ doped In₂O₃, with the doping concentration (by weight) of TiO₂ between 0.2 and 2%, and the doping concentration (by weight) of Ta₂O₅ between 0 and 1%. These targets can be rotary targets and can be located at both sides of the substrates to allow for double-sided deposition. PVD chamber 602 can be configured to perform the TCO deposition without intentional heating of the substrate. The inherent heating caused by the deposition process may raise the substrate temperature to about 130° C. In some embodiments, PVD chamber 602 can be coupled to a cooling system (e.g., a water cooling system) that can maintain the temperature of the substrate below 80° C.

Annealing chamber 606 can couple PVD chambers 602 and 604. More specifically, annealing chamber 606 and PVD chambers 602 and 604 belong to the same vacuum environment. During fabrication, photovoltaic structures can be transferred from PVD chamber 602 to annealing chamber 606, and to PVD chamber 604 without disrupting the vacuum. More specially, subsequent to the deposition of the TCO layers, photovoltaic structures can be transferred (e.g., via an internal robotic mechanism or conveyor system) from PVD chamber 602 to annealing chamber 606, which can include a heating element (e.g., a resistive heating element or an arc-lamp heating element). In some embodiments, the heating element can raise the temperature of the substrates to a temperature between 150 and 230° C. The photovoltaic structures can be kept in annealing chamber 606 for a predetermined time before being sent to PVD chamber 604. In order to prevent disturbance to the temperature setting in PVD chambers 602 and 604, annealing chamber 606 can be thermally insulated from the PVD chambers.

PVD chamber 604 can be responsible for depositing a metallic seed layer (e.g., a Cu seed layer) on the TCO layer. Because deposition temperature is not a critical factor for the Cu deposition, there is no need for heating or cooling down of the substrates inside PVD chamber 604. On the other hand, it is also possible to incorporate part or the entirety of the TCO annealing process into the Cu deposition process.

In some embodiments, PVD chamber 604 can be configured to perform Cu deposition at an elevated temperature. Under certain deposition settings, the plasma heating alone can raise the temperature of the substrates to about 200° C. By controlling the amount of time photovoltaic structures spend in PVD chamber 604, it can be possible to complete the entire TCO annealing process inside PVD chamber 604. This makes annealing chamber 406 optional. Incorporating TCO annealing with Cu deposition can further simplify the fabrication process. Alternatively, one can configure PVD system 600 in such a way that, after the TCO deposition in PVD chamber 602, the TCO layers can be partially annealed in annealing chamber 606 and then further annealed during the Cu deposition in PVD chamber 604. The cumulative effect can transform amorphous TCO to multicrystalline TCO.

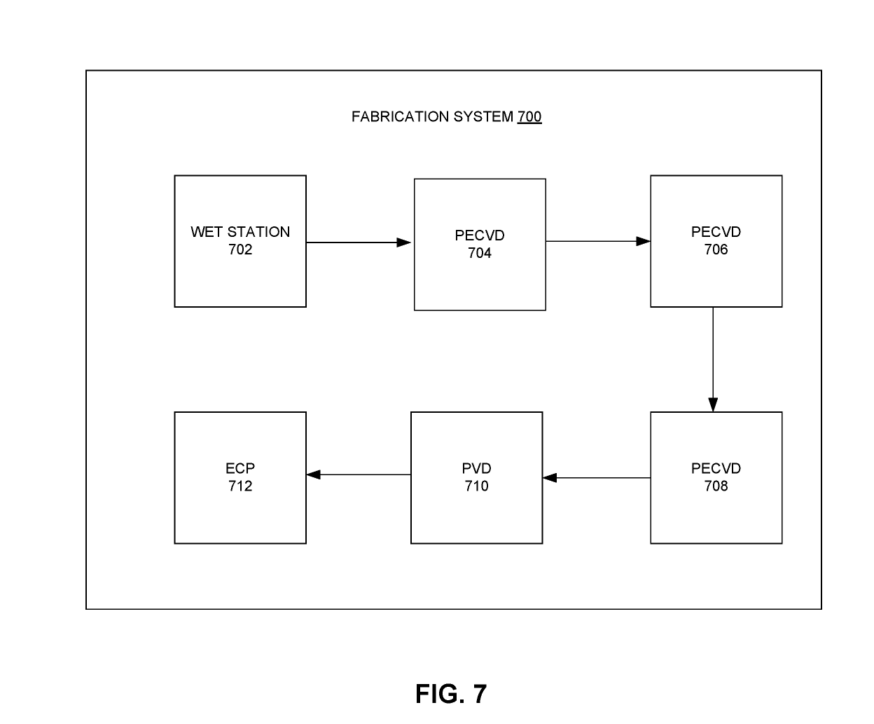

FIG. 7 shows an exemplary fabrication system, according to one embodiment. Fabrication system 700 can include wet station 702, PECVD tools 704, 706, and 708, PVD tool 710, and ECP tool 712. Wet station 702 and ECP tool 708 can be similar to wet station 302 and ECP tool 310 shown in FIG. 3, respectively. PECVD tools 704-708 can be similar to PECVD tool 304 shown in FIG. 3, and can be configured to deposit the intrinsic and doped a-Si layers. PVD tool 706 can be similar to PVD tool 600 shown in FIG. 6. Because PVD tool 706 includes an annealing chamber between its two PVD chambers, fabrication system 700 no longer needs an external annealing too.

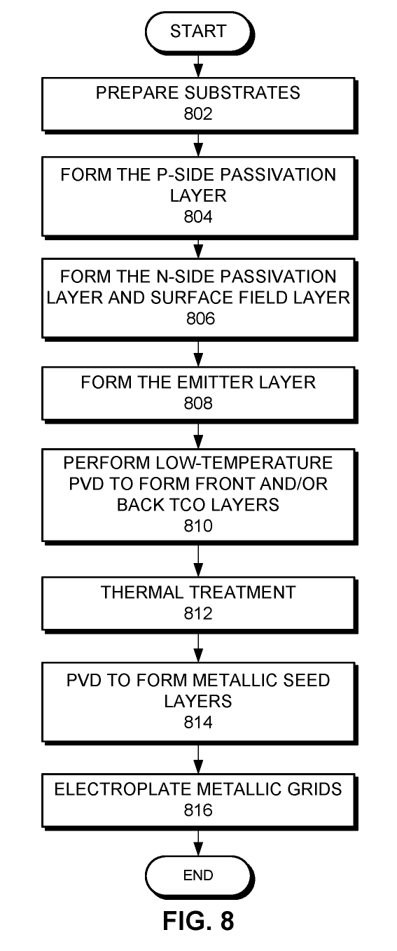

FIG. 8 shows an exemplary fabrication process, according to one embodiment. The following process is described in conjunction with FIG. 7.

During operation, a number of Si substrates can be prepared (operation 802). The Si substrates can be lightly doped with n-type dopants, and can go through, at wet station 702, saw damage removing, random texturing, and cleaning. The n-type doped substrates can be sent to PEVCD tool 704 for deposition of an intrinsic a-Si on one side, which can act as the p-side passivation layer (operation 804). Subsequently, the substrates can be flipped over and sent to PECVD tool 706 for the sequential deposition of the n-side passivation layer (which can also include an intrinsic a-Si layer) and the surface-field layer (which can include an n-type doped a-Si layer) (operation 806). The substrates can then be turned over again and sent to PECVD tool 708 for the deposition of the emitter layer, which can include a p-type doped a-Si layer (operation 808). Operations 802-808 can be similar to operations 502-508 shown in FIG. 5.

Subsequently, a low-temperature PVD can be performed, inside a first chamber of PVD tool 710 to form the front and/or back TCO layers (operation 810). Operation 808 can be similar to operation 408 shown in FIG. 4. More specifically, during the TCO deposition, the temperature of the substrates can be kept below 130° C. (preferably below 80° C.), such that the deposited TCO layers are in an amorphous state.

After the TCO deposition, thermal treatment can be applied to at least partially anneal the TCO layers (operation 812). In some embodiments, the thermal treatment can be performed in-situ, meaning that the photovoltaic structures can be annealed within the same PVD tool. For example, the photovoltaic structures can be transferred to an annealing chamber positioned inside PVD tool 710 without disrupting the vacuum. In alternative embodiments, the thermal treatment can occur outside of PVD tool 710. For example, the photovoltaic structures can be transferred to a separate annealing oven or furnace. Because there is no metallic seed layer, thermal annealing can be performed in air. However, this can lead to increased fabrication time, because the subsequent operation may require the photovoltaic structures to be sent back into a vacuum chamber.

After the thermal treatment, metallic seed layers can be formed using a PVD technique (operation 812). Operation 812 can be similar to operation 410 shown in FIG. 4. In some embodiments, PVD deposition of a Cu seed layer can be performed under an elevated temperature, and can contribute to the annealing of the TCO, thus reducing the time needed for photovoltaic structures to remain in the annealing chamber. It is preferable to perform the PVD deposition of the Cu seed layer in the same tool (e.g., PVD tool 710) that deposits the TCO layers, because this can save equipment cost and also provide a more streamlined fabrication process. By using a same PVD tool (e.g., a PVD tool with multiple chambers or multiple targets) to deposit both the TCO and metallic seed layers, there is no longer a need to unload the photovoltaic structures from one PVD tool and load them into another PVD tool, or to wait for the deposition chambers to be pumped down after the loading/unloading. Consequently, the production time of one batch of photovoltaic structures can be significantly reduced.

The system can be configured in a way such that the cumulative heating of the TCO layers during operations 812 and 814 can sufficiently anneal the TCO layers to improve their electro-optical properties, and no additional heating will be needed. Alternatively, the photovoltaic structures can go through an optional oxygen-free thermal treatment after the formation of the metallic seed layers to ensure that the TCO layers are sufficiently annealed. Note that after a saturation point, prolonged heating of the photovoltaic structures cannot improve the electro-optical properties of the TCO layers any further. Due to the existence of the metallic seed layer, this optional annealing operation needs to be performed in an oxygen-free environment, which can be achieved by introducing strong flows of purging gas (e.g., N₂).

After the TCO layers are sufficiently annealed, the photovoltaic structures can be sent to an electroplating station for plating of the front and back side metallic grids (operation 816). Operation 816 can be similar to operation 414 shown in FIG. 4.

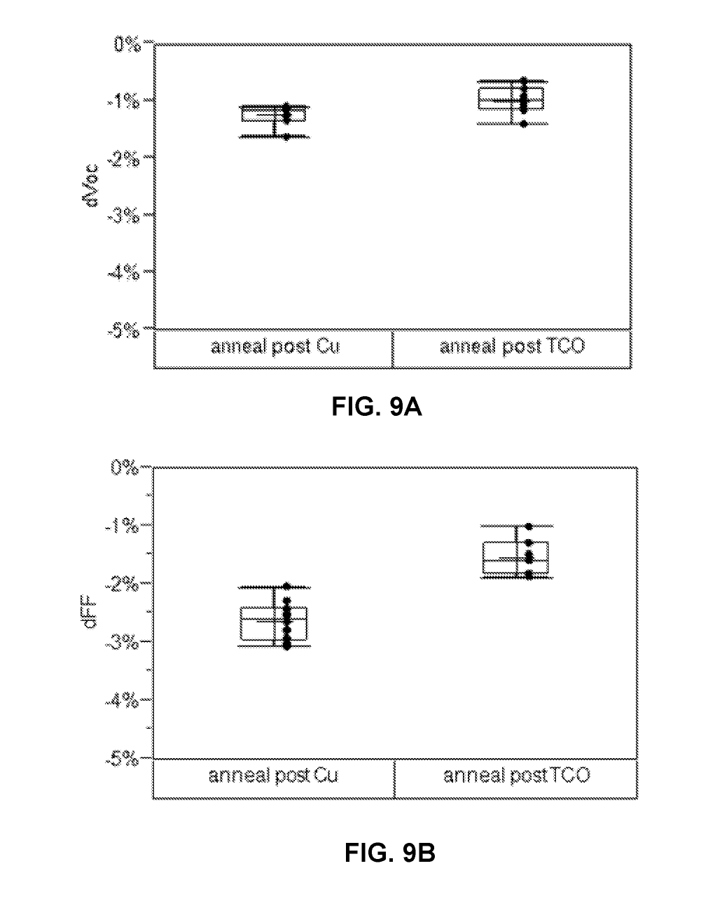

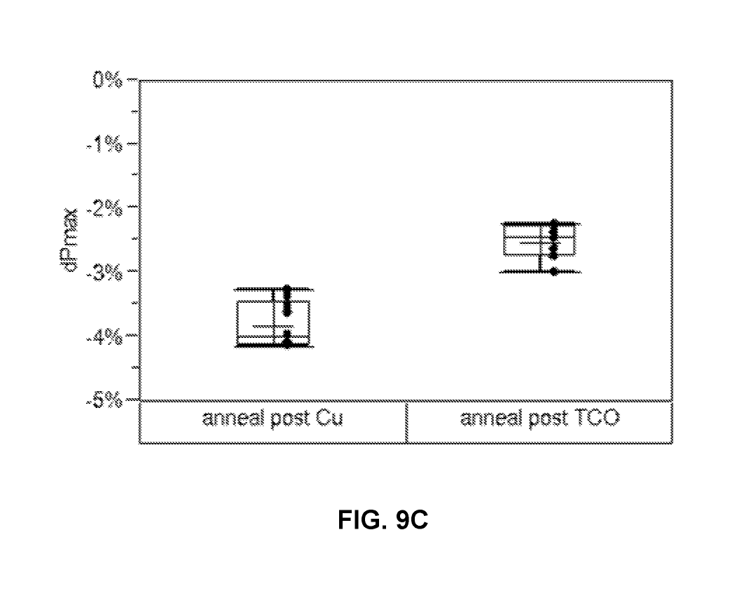

Regardless of whether the thermal annealing is taking place before or after the deposition of the metallic seed layers, the resulting TCO layers can have superior moisture resistant properties. FIGS. 9A-9C show the highly-accelerated temperature and humidity stress test (HAST) results, according to one embodiment. More specifically, FIGS. 9A-9C show the degradation of the open-circuit voltage (V_{oc}), fill factor (FF), and maximum power output (Pₘₐₓ), respectively, of the photovoltaic structures after 168 hours of HSAT test. The test condition is set at a temperature of 121° C. with 100% relative humidity. From FIGS. 9A-9C, one can see that the performance degradation of the photovoltaic structures is less than 4% for both annealing scenarios. For example, the degradation of Pₘₐₓ can be between 3% and 4%, if the annealing is performed after the electroplating of the Cu grids. On the other hand, the degradation of Pₘₐₓ can be between 2% and 3%, if the annealing is performed after the deposition of the TCO layers, but before the electroplating of the Cu grids.

The novel fabrication system/process provided by embodiments of the present invention can provide a number of advantages. More specifically, depositing the TCO layers without intentional heating can improve system throughput, because there is no longer a need to wait for the temperature to stabilize. In addition, the unique TCO material composition combined with its fabrication process (e.g., the non-heating PVD followed by low-temperature (around 200° C.) annealing) can provide high-quality TCO films, which not only have superior electro-optical properties (e.g., transparency and resistivity), but can also serve as reliable moisture barriers. Furthermore, the fabricated TCO layers can prevent the diffusion of the metallic ions from the metallic seed layer. Overall, this novel fabrication system/process can produce, with high throughput, photovoltaic structures that have a higher V_{oc}, higher TCO transparency, lower TCO resistivity, lower grid resistivity, and better long-term reliability.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a photovoltaic structure, comprising:
depositing a doped amorphous Si layer on a first surface of a crystalline Si substrate;
depositing, using a physical vapor deposition machine, a transparent conductive oxide layer on the doped amorphous Si layer, wherein depositing the transparent conductive oxide layer involves maintaining the Si substrate at a temperature below 130° C., and wherein the transparent conductive oxide layer comprises In₂O₃ doped with TiO₂ and Ta₂O₅;
depositing a metallic layer on the transparent conductive oxide layer; and
annealing the transparent conductive oxide layer.

2. The method of claim 1, wherein depositing the transparent conductive oxide layer further involves maintaining the Si substrate at a temperature below 80° C.

3. The method of claim 1, wherein depositing the transparent conductive oxide layer further involves injecting H₂ or water vapor into the physical vapor deposition machine.

4. The method of claim 1, wherein a by-weight concentration of the TiO₂ is between 0.2% and 2%, and wherein a by-weight concentration of the Ta₂O₅ is between 0 and 1%.

5. The method of claim 1, wherein annealing the transparent conductive oxide layer involves subjecting the photovoltaic structure to a temperature ranging from 150° C. to 230° C.

6. The method of claim 5, wherein annealing the transparent conductive oxide layer comprises subjecting the photovoltaic structure to the temperature for a time period between three and 90 minutes.

7. The method of claim 1, wherein annealing the transparent conductive oxide layer is performed after the metallic layer is deposited, wherein the metallic layer is deposited in the same physical vapor deposition tool without disrupting a vacuum, and wherein the annealing is performed in an oxygen-free environment to prevent oxidation of the metallic layer.

8. The method of claim 1, wherein annealing the transparent conductive oxide layer is performed before the deposition of the metallic layer, and wherein the annealing is performed inside the physical vapor deposition tool without disrupting a vacuum.

9. The method of claim 8, wherein depositing the metallic layer involves heating the Si substrate, thereby facilitating at least a portion of the annealing of the transparent conductive oxide layer.

10. A photovoltaic structure, comprising:
a Si-based substrate;
a first doped amorphous Si layer positioned on the first side of the Si-based substrate;
a first transparent conductive oxide layer on the first doped amorphous Si layer, wherein the first transparent conductive oxide layer comprises In₂O₃ doped with TiO₂ and Ta₂O₅; and
a first electroplated metallic grid on the first transparent conductive oxide layer.

11. The photovoltaic structure of claim 10, wherein a by-weight concentration of the TiO₂ is between 0.2% and 2%, and wherein a by-weight concentration of the Ta₂O₅ is between 0 and 1%.

12. The photovoltaic structure of claim 10, wherein the first transparent conductive oxide layer is formed using a physical vapor deposition process, which involves maintaining the Si-based substrate at a temperature below 80° C.

13. The photovoltaic structure of claim 10, further comprising:
a second doped amorphous Si layer positioned on the second side of the Si-based substrate;
a second transparent conductive oxide layer on the second doped amorphous Si layer, wherein the second transparent conductive oxide layer comprises In₂O₃ doped with TiO₂ and Ta₂O₅.

14. A fabrication system, comprising:
a physical vapor deposition tool configured to sequentially deposit a transparent conductive oxide layer and a metallic layer on a photovoltaic structure, wherein the transparent conductive oxide layer comprises In₂O₃ doped with TiO₂ and Ta₂O₅, and wherein the physical vapor deposition tool is configured to maintain the photovoltaic structure at a temperature below 130° C. while depositing the transparent conductive oxide layer; and
a thermal annealing tool configured to anneal the transparent conductive oxide layer.

15. The system of claim 14, wherein the physical vapor deposition tool includes a cooling mechanism configured to maintain the photovoltaic structure at a temperature below 80° C.

16. The system of claim 14, wherein, while depositing the transparent conductive oxide layer, the physical vapor deposition tool is configured to receive H₂ or water vapor.

17. The system of claim 14, wherein a by-weight concentration of the TiO₂ is between 0.2% and 2%, and wherein a by-weight concentration of the Ta₂O₅ is between 0 and 1%.

18. The system of claim 14, wherein the thermal annealing tool is configured to subject the photovoltaic structure to a temperature ranging from 150° C. to 230° C. for a time period between three and 90 minutes.

19. The system of claim 14, wherein the physical vapor deposition tool includes a first chamber for depositing the transparent conductive oxide layer and a second chamber for depositing the metallic layer, wherein the thermal annealing tool is part of the physical vapor deposition tool and is positioned between the first chamber and the second chamber such that the transparent conductive oxide layer is annealed before the deposition of the metallic layer.

20. The system of claim 19, wherein the second chamber is configured to deposit the metallic layer at an elevated temperature, thereby facilitating at least a portion of the annealing of the transparent conductive oxide layer.
